(19) United States
(12) Patent Application Publication
(10) Pub. No.: US 2017/0260629 A1
(43) Pub. Date: Sep. 14, 2017

(54) Quartz crystal microbalance assembly for ALD systems

(71) Applicant: Ultratech, Inc., San Jose, CA (US)

(72) Inventors: Laurent Lecordier, Arlington, MA (US); Michael Ruffo, Medford, MA (US)

(73) Assignee: Ultratech, Inc., San Jose, CA (US)

(21) Appl. No.: 15/435,333

(22) Filed: Feb. 17, 2017

Related U.S. Application Data
(60) Provisional application No. 62/304,968, filed on Mar. 8, 2016.

(51) Int. Cl. C23C 16/455; C23C 16/52

(52) U.S. Cl. CPC C23C 16/45544; C23C 16/52

(57) ABSTRACT

A quartz crystal microbalance assembly includes a lid of a reactor chamber of an ALD system. A QCM crystal is disposed in a bottom section of a central cavity formed in the lid. A central portion of a front surface of the QCM crystal is exposed to an interior of the reactor chamber. A retainer arranged within the central cavity and above the QCM crystal presses the QCM crystal against a ledge in the lid to form a seal between the front surface of the QCM crystal and the ledge while also establishing electrical contact with the QCM crystal. A flange resides immediately adjacent a top surface of the lid and seals the central cavity while supporting electrical contact with the QCM crystal through the retainer. A transducer external to the reactor chamber and in electrical contact with the QCM crystal through a connector in the flange drives the QCM crystal.

### CROSS-REFERENCE TO RELATED APPLICATIONS

This Application claims the benefit of priority under 35 USC 119(e) of U.S. Provisional Patent Application Ser. No. 62/304,968, filed on Mar. 8, 2016, and which is incorporated by reference herein.

### FIELD

The present disclosure relates to atomic-layer deposition (ALD), and in particular relates to a quartz crystal microbalance assembly for ALD systems.

The entire disclosure of any publication or patent document mentioned herein is incorporated by reference.

### BACKGROUND

Atomic layer deposition (ALD) is a method of depositing a thin film on a substrate in a very controlled manner. The deposition process is controlled by using one or more chemicals (“precursors”) in vapor form and reacting them sequentially and in a self-limiting manner on the surface of the substrate. The sequential process is repeated to build up the thin film layer by layer, wherein the layers are atomic scale.

ALD is used to form a wide variety of films, such as binary, ternary and quaternary oxides for advanced gate and capacitor dielectrics, as well as metal-based compounds for interconnect barriers and capacitor electrodes. An overview of the ALD process is presented in the article by George, entitled “Atomic Layer Deposition: an Overview,” Chem. Rev. 2010, 110, pp 111-113 (published on the Web on Nov. 20, 2009). The ALD process is also described in U.S. Pat. No. 7,128,787. Example ALD systems are disclosed in U.S. Patent Application Publication No. US2006/0021573 and PCT Publication No. WO 2015/080979.

ALD films are typically characterized post-process via an ex-situ measurement of the deposited film thickness using for example ellipsometry or other techniques. However, in-situ film characterization techniques would generally be more preferred because they can provide essential real-time growth information about the ALD process.

Quartz crystal microbalances (QCMs) have been used to measure film growth in a variety of thin-film deposition systems, and in particular physical vapor deposition (PVD) systems. Some attempts have been made to apply QCMs to ALD systems. Unfortunately, to date there is no truly commercially viable QCM. This is due in large measure to the key technical challenges inherent to ALD and QCM technology. For example, one technical challenge relates to the small deposition rates of ALD, which are typically in the range of 0.1 nm to 10 nm/min. Even though the resolution of a QCM can be as low as 0.01 nm, the impact of disturbances on the crystal resonant frequency are more much severe than in other film-deposition process with greater deposition rates, such as PVD.

Another technical challenge is the thermal nature of ALD. ALD typically uses temperatures in the range of 50° C. to 350° C. Because the QCM measurement is temperature dependent, the QCM must be thermally stable.

An additional challenge relates to the high degree of conformality of the ALD process. ALD films can deposit very uniformly even within 3D recesses that are out of the line of sight of the reactant source. Thus, without precautionary measures, ALD can also deposit a film inside a QCM sensor and hinder its operation. This can occur, for example, by inadvertently depositing a dielectric film on the electrical contacts on the backside of the QCM crystal of the QCM sensor, thereby electrically insulating the QCM crystal from the electronic components of the QCM circuit. Efforts to obviate this problem have included the use of epoxy to seal off the backside of the QCM, and the use of a purge gas. Unfortunately, the use of epoxy in a commercial ALD system is undesirable because of the difficulties of its proper application and because the epoxy introduces unwanted chemical material into the chamber environment. The flow of a purge gas to mitigate unwanted film deposition on the QCM is also problematic because it can impact the flow dynamics within the reactor chamber interior and adversely affect the film growth. A back flow purge can also induce signal noise as the gas flows around the crystal and requires active management of the pressure differential between the backside of the QCM crystal and the reactor chamber interior. Such active management is complicated and costly.

Another challenge relates to reactor chamber size. Most commercial ALD reactors have a small reactor chamber volume to optimize the process cycle time. For example, the Savannah ALD system from Ultratech/Cambridge Nanotech of Waltham Massachusetts has a circular reactor chamber of 100 mm to 300 mm with only about a 5 mm height. Because of the very limited reactor chamber volume, existing QCM configurations, including so-called “on a stick’ configurations, are unsuitably large and unwieldy for practical use.

### SUMMARY

An aspect of the disclosure is a QCM assembly for an ALD system having a reactor chamber with an interior. The QCM assembly includes a lid of the reactor chamber. The lid has a central cavity. The QCM assembly also includes a QCM crystal having a front surface, a back surface and a diameter DQ. The QCM crystal is disposed in a bottom section of the central cavity with the front surface in contact with a ledge so that a central portion of the front surface resides adjacent a QCM opening, which has a diameter DO. In this arrangement, the central portion of the front surface of the QCM crystal is exposed to the interior through the QCM opening. Further, the diameter DO satisfies the condition (0.25)DQ≦DO≦(0.6)DQ. The QCM assembly also includes a retainer having an upper surface and downwardly depending conductive resilient members. The retainer is arranged within the central cavity with the conductive resilient members in electrical contact with the QCM crystal. The conductive resilient members press against the QCM crystal so that the outer portion of the front surface of the QCM crystal is pressed against the ledge. This forms a first seal between the front surface of the QCM crystal and the ledge. The QCM assembly also includes a flange. The flange has a central portion that closely resides within a top section of the central cavity and immediately adjacent the retainer. The flange also has an outer portion with a lower surface that resides immediately adjacent a top surface of the lid and that forms a second seal therewith. The flange operably supports an electrical contact member that makes electrical contact with the retainer.

Another aspect of the disclosure is the QCM assembly as described above, wherein the first seal does not include either a sealing material or a sealing member.

Another aspect of the disclosure is the QCM assembly as described above, wherein there is no flow of a purge gas within the central cavity.

Another aspect of the disclosure is the QCM assembly as described above, wherein (0.25)DQ≦DO≦(0.4)DQ.

Another aspect of the disclosure is the QCM assembly as described above, wherein the QCM assembly further includes a transducer electrically connected to the retainer through the flange.

Another aspect of the disclosure is the QCM assembly as described above, wherein the QCM assembly further includes a controller electrically connected to the transducer.

Another aspect of the disclosure is the QCM assembly as described above, wherein the QCM assembly further includes a base operably attached to the lid to define the reactor chamber.

Another aspect of the disclosure is the QCM assembly as described above, wherein the QCM assembly further includes a thermally insulating cover sized to cover the reactor chamber.

Another aspect of the disclosure is the QCM assembly as described above, wherein the interior of reactor chamber has a height in the range from 3 mm to 50 mm.

Another aspect of the disclosure is a QCM assembly for an ALD system having a reactor chamber with a lid. The QCM assembly includes the lid, wherein the lid has a top surface, a bottom surface and a central cavity. The central cavity includes a flange opening at the top surface that leads to a top section of the central cavity. The central cavity also includes a QCM opening at the bottom surface that leads to a bottom section of the central cavity. The QCM opening has a diameter DO defined by a ledge. The central cavity also has a middle section between the top and bottom sections. The top surface of the lid includes an O-ring groove that runs around the central cavity and that operably supports an O-ring. The QCM assembly also includes a QCM crystal having a front surface, a back surface and a diameter DQ. The QCM crystal is disposed in the bottom section of the central cavity with the front surface in contact with the ledge so that a central portion of the front surface resides adjacent the QCM opening. The diameter DO of the QCM opening satisfied the condition (0.25)DQ≦DO≦(0.6)DQ. The QCM assembly also includes a retainer arranged in the middle section of the central cavity. The retainer has an upper surface and downwardly depending conductive resilient members. The conductive resilient members are in contact with the back surface of the QCM crystal and press an outer portion of the front surface of the QCM crystal into the ledge to form a first seal. The QCM crystal also includes a flange having a central portion that closely resides within the top section of the central cavity. The flange has an outer portion with a lower surface that resides immediately adjacent the top surface of the lid and that forms a second seal with the O-ring. The flange operably supports a connector that includes an electrical contact member that makes electrical contact with the retainer.

Another aspect of the disclosure is the QCM assembly as described above, wherein (0.25)DQ≦DO≦(0.4)DQ.

Another aspect of the disclosure is the QCM assembly as described above, wherein the QCM assembly further includes a transducer electrically connected to the retainer through the flange.

Another aspect of the disclosure is the QCM assembly as described above, wherein the QCM assembly further includes a controller electrically connected to the transducer.

Another aspect of the disclosure is the QCM assembly as described above, wherein the QCM assembly further includes a base operably attached to the lid to define the reactor chamber.

Another aspect of the disclosure is the QCM assembly as described above, wherein the QCM assembly further includes a thermally insulating cover sized to cover the reactor chamber.

Another aspect of the disclosure is a method of performing an in situ measurement of film growth in an ALD system that includes a reactor chamber having an interior defined by a base and a lid and that operably supports a substrate. The method includes providing a QCM assembly integrated with the lid. The QCM assembly has a QCM crystal with a front surface. The QCM assembly is disposed on a ledge in a bottom section of a cavity formed in the lid so that a central portion of the QCM crystal is exposed to the interior of reactor chamber and above the substrate while a retainer member presses an outer portion of the front surface of the QCM crystal against the ledge to form a seal that does not include either a sealing material or a sealing member; the method also includes performing an ALD process in the interior of reactor chamber to deposit a first film on the substrate and a second film on the central portion of the QCM crystal while driving the QCM crystal with a transducer and measuring an output signal from the QCM crystal.

Another aspect of the disclosure is the method as described above, wherein the QCM crystal has a diameter DQ the central portion of the surface of QCM crystal has a diameter DO, and wherein (0.25)DQ≦DO≦(0.6)DQ.

Another aspect of the disclosure is the method as described above, wherein said pressing is performed by downwardly depending conductive resilient members of the retainer, which resides immediately above the QCM crystal and within the cavity in the lid.

Another aspect of the disclosure is the method as described above, the method further includes thermally insulating the QCM assembly with a thermally insulated cover disposed over the lid.

Another aspect of the disclosure is the method as described above, wherein the interior has a height in the range from 3 mm to 50 mm.

Another aspect of the disclosure is a QCM assembly for an ALD system. The QCM assembly includes a lid of a reactor chamber of the ALD system. The lid has a central cavity with a bottom section that includes a ledge that defines an opening to an interior of the reactor chamber. A QCM crystal with a front surface is disposed in the bottom section of the central cavity, with an outer portion of the front surface in contact with the ledge so that a central portion of the front surface is exposed to the reactor chamber through the opening; The QCM assembly also includes a retainer arranged within the central cavity above the QCM crystal. The retainer is configured to press the outer portion of the front surface of the QCM crystal against the ledge to form a seal between the QCM crystal and the ledge while also forming electrical contact between the retainer and the QCM crystal. The QCM assembly further includes a flange disposed immediately adjacent a top surface of the lid. The flange seals the central cavity while providing electrical contact with the QCM crystal through the retainer. The QCM assembly also includes a transducer external to the ALD reactor chamber and that is electrically connected to the QCM crystal through the flange and the retainer.

Additional features and advantages are set forth in the Detailed Description that follows, and in part will be readily apparent to those skilled in the art from the description or recognized by practicing the embodiments as described in the written description and claims hereof, as well as the appended drawings. It is to be understood that both the foregoing general description and the following Detailed Description are merely exemplary, and are intended to provide an overview or framework to understand the nature and character of the claims.

### BRIEF DESCRIPTION OF THE DRAWINGS

The accompanying drawings are included to provide a further understanding, and are incorporated in and constitute a part of this specification. The drawings illustrate one or more embodiment(s), and together with the Detailed Description serve to explain principles and operation of the various embodiments. As such, the disclosure will become more fully understood from the following Detailed Description, taken in conjunction with the accompanying Figures, in which:

FIG. 1A is a front elevated view of an example ALD system;

FIG. 1B is a close-up front elevated view of the example ALD system of FIG. 1A showing the insulated cover in the closed position over the reactor chamber;

FIG. 2 is front elevated view of a reactor assembly of the ALD system of FIG. 1;

FIG. 3 is a front-elevated close-up view of the reactor assembly of FIG. 2 with the lid of the reactor chamber in the dosed position and showing a portion of the flange and connector of the QCM assembly.

FIG. 4 is a close-up cross-sectional view of a central portion of the lid of the reactor chamber, showing an example configuration of the central cavity used to accommodate components of the QCM assembly;

FIG. 5A is partially exploded cross-sectional view of the central portion of the lid of the reactor chamber as shown in FIG. 4 along with the components of the QCM assembly;

FIG. 5B is similar to FIG. 5A and shows the components of the QCM assembly in their assembled form, and also showing the base of the reactor chamber with a wafer disposed within the interior of reactor chamber;

FIG. 6A is a close-up cross-sectional view of the bottom section of the central cavity showing the QCM crystal operably arranged on the ledge therein so that a central portion of the QCM crystal resides over the QCM opening and is exposed to the interior of the reactor chamber; and

FIG. 6B is a face-on view of an example QCM crystal showing the annular outer portion of the QCM crystal supported by the ledge and the central portion of the QCM crystal that resides over the QCM opening.

### DETAILED DESCRIPTION

Reference is now made in detail to various embodiments of the disclosure, examples of which are illustrated in the accompanying drawings. Whenever possible, the same or like reference numbers and symbols are used throughout the drawings to refer to the same or like parts. The drawings are not necessarily to scale, and one skilled in the art will recognize where the drawings have been simplified to illustrate the key aspects of the disclosure.

The claims as set forth below are incorporated into and constitute part of this Detailed Description.

Cartesian coordinates are shown in some of the Figures for the sake of reference and ease of illustration and discussion, and are not intended to be limiting as to direction or orientation.

ALD System

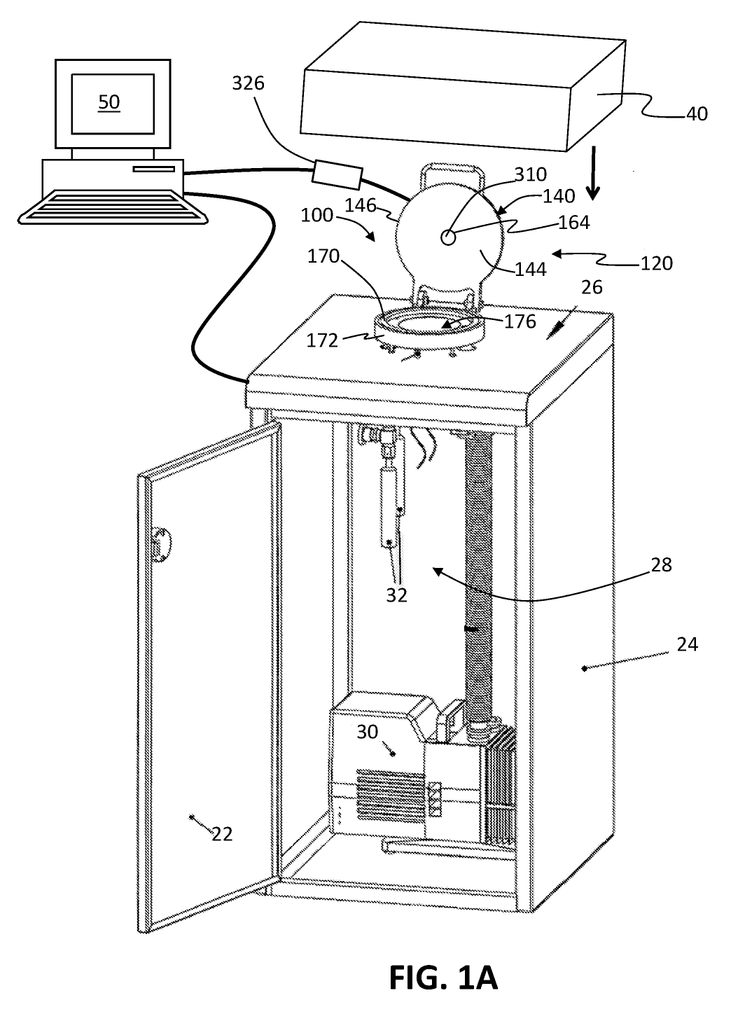

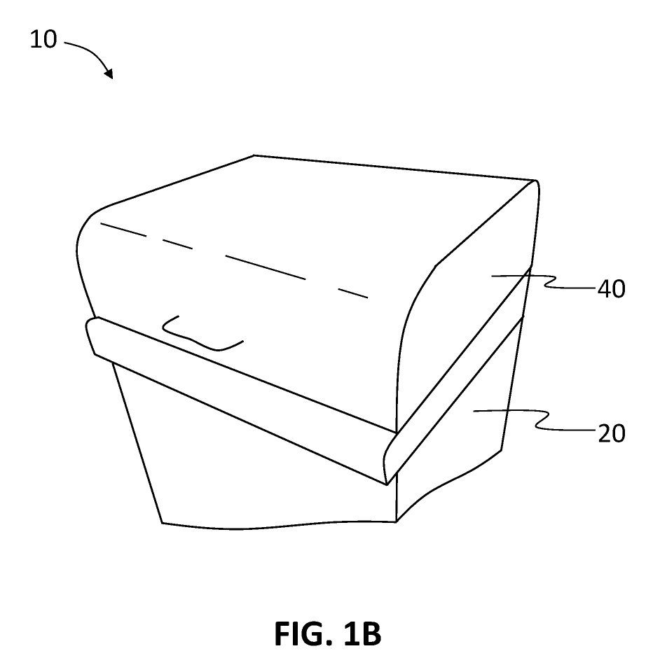

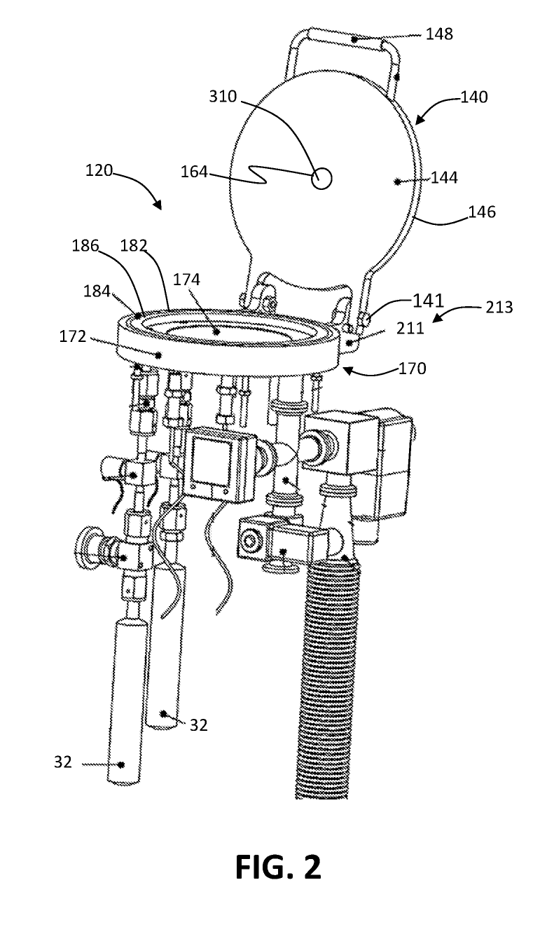

FIG. 1A is a front elevated view of an example ALD system 10, while FIG. 1B is a close-up front elevated view of the ALD system 10 and FIG. 2 is a front elevated view of a reactor assembly 100 of the example ALD system 10. The ALD system 10 briefly described herein is also described in greater detail in U.S. Pat. No. 8,202,575.

The ALD system 10 has a cabinet 20 that includes a door 22, side panels 24, and a top panel 26 that supports the reactor assembly 100. The cabinet 20 includes an interior 28 sized to accommodate the various components of reactor assembly 100 and ALD system 10, such as a vacuum pump 30 and precursor gas cannisters 32, as well as other components such as control electronics, valves, vacuum lines and like parts (not shown).

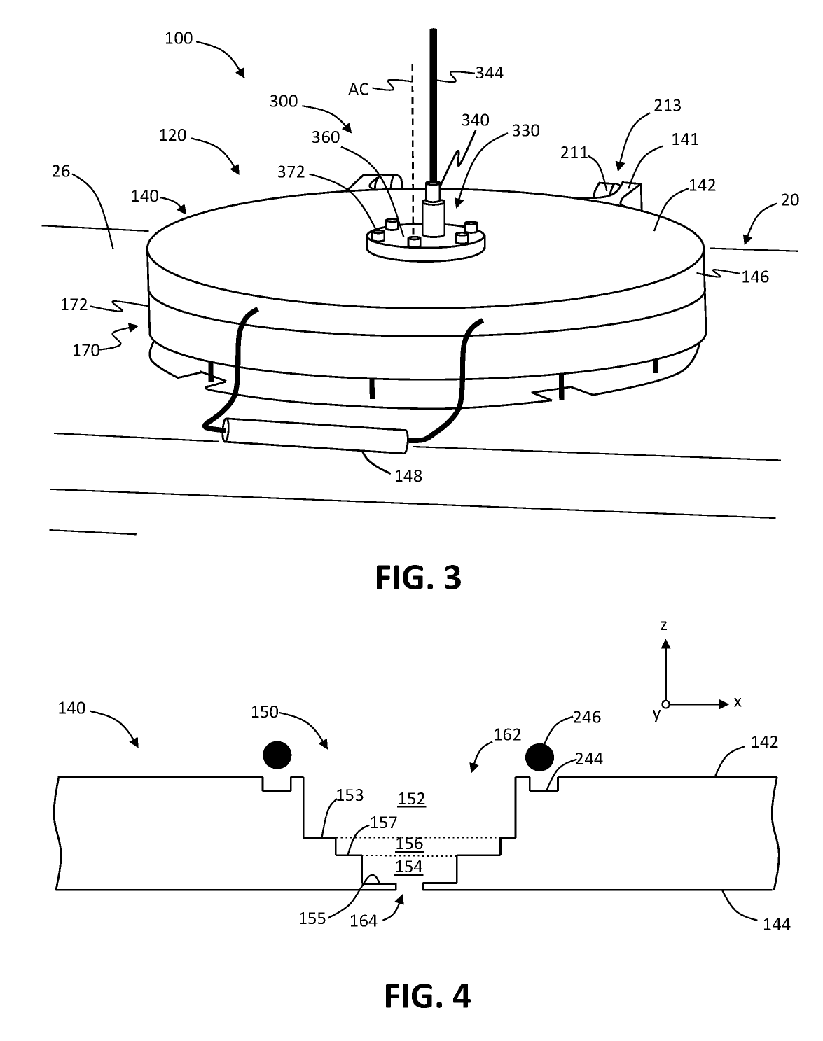

The reactor assembly 100 includes a reactor chamber 120 that resides on the top panel 26 of cabinet 20. The ALD system 10 includes an insulated cover 40 that is sized to cover the reactor chamber 120 and the corresponding components of the QCM assembly 300 as introduced and described below. The insulated cover 40 is useful for thermally insulating the QCM assembly 300 and for reducing thermal disturbances and thus measurement noise. The insulated cover 40 can be hinged to the top panel 26 of cabinet 20 as shown in FIG. 1B, or can be unconnected to the cabinet 20 and placed onto and removed from the top panel 26 as needed, as shown in FIG. 1A. FIG. 3 is a front-elevated close-up view of the reactor assembly 100 with a lid 140 in the closed position and that shows an external portion of QCM assembly 300.

The ALD system 10 further includes a controller 50 (e.g., a computer) that controls the operation of the ALD system 10 and can also serve as a display and controller for the QCM assembly 300 disclosed herein and as discussed in greater detail below.

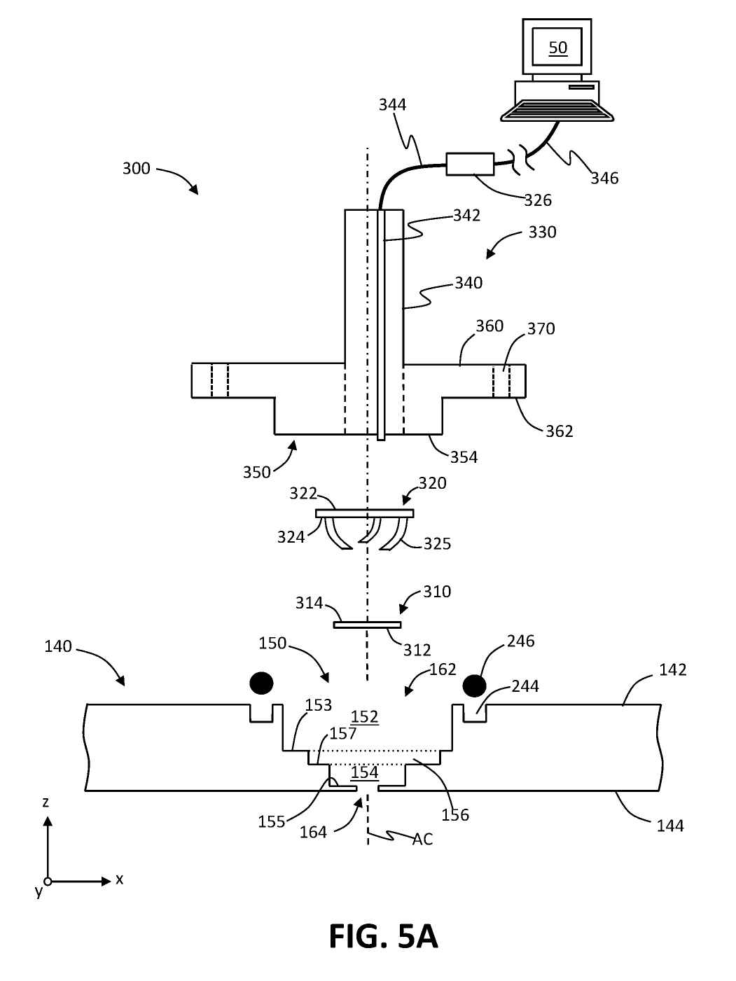

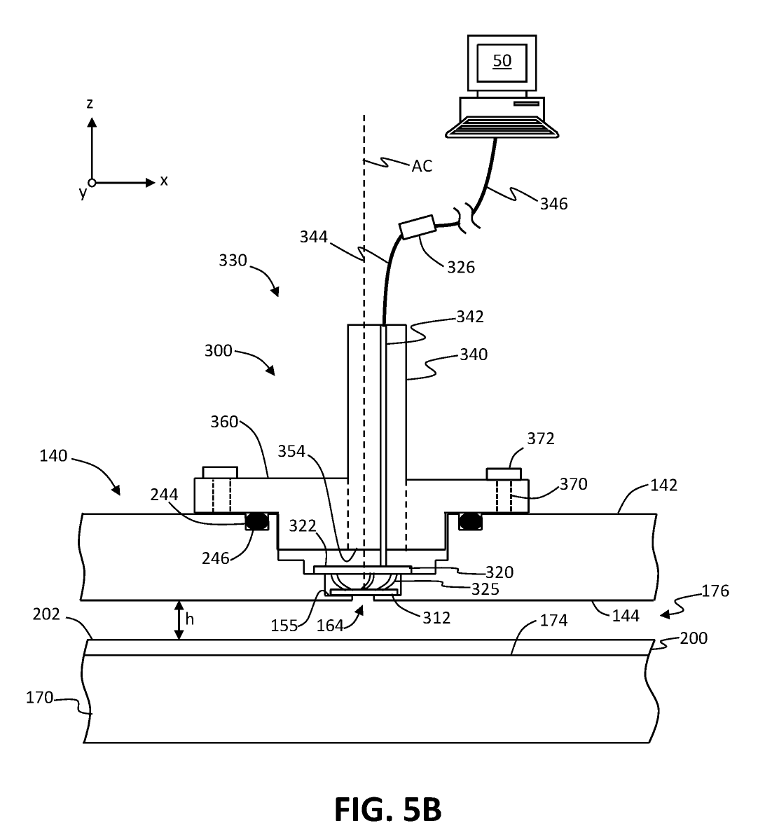

The reactor chamber 120 of reactor assembly 100 is defined by the lid 140 and a base 170. The lid 140 includes a top surface 142, a bottom surface 144, a side 146 and a handle 148. In an example, the base 170 has a cylindrical shape defined by a cylindrical wall 172. The base 170 also includes a floor 174 sized to accommodate a large (e.g., 100 mm or 300 mm) semiconductor substrate (wafer) 200 having an upper surface 202 (see FIG. 5B). The cylindrical wall 172 has a generally flat top surface 182 that includes a groove 184 that supports an O-ring 186. The cylindrical wall 172, the floor 174 and the lid 140 define an interior 176. The O-ring 186 serves to form a seal between the lid 140 and the base 170 to seal the interior 176 during ALD processing. Thus, the lid 140 serves to define a closed interior 176, which has a height h (see FIG. 5B). In an example, the height h can be in the range from 3 mm to 50 mm, with an exemplary height being nominally 5 mm.

The base 170 also includes hinge fixtures 211 that engage hinge fixtures 141 of the lid 140 to form a hinge 213 that allows the lid 140 to be placed in a closed or open position relative to the base 170. The lid 140 thus serves to make the interior 176 closed and sealed when the lid 140 is in the closed position and open when the lid 140 is in the open position.

The base 170 is preferably formed of a low thermal conductivity material, such as stainless steel. The reactor chamber 120 includes a central axis AC that runs in the z-direction and generally through the center of lid 140 and base 170 (see FIG. 3).

FIG. 4 is a close-up cross-sectional view of a central portion of the lid 140. The lid 140 includes a central cavity 150 open at the top and bottom surfaces 142 and 144. The central cavity 150 includes a top section 152 adjacent the top surface 142, a bottom section 154 adjacent the bottom surface 144, and a middle section 156 between the top and bottom sections 152 and 154. In an example, the top and bottom sections 152 and 154 of the central cavity 150 each has a generally circular cross-sectional shape while the middle section 156 has a rectangular shape that matches the size and shape of a retainer 320, which is introduced below.

The top section 152 includes a wide central opening 162 at the top surface 142, which is referred to hereinafter as the “flange opening.” The central cavity 150 also has a relatively narrow central opening 164 in the bottom section 154 at the bottom surface 144. The narrow central opening 164 is referred to hereinafter as the “QCM opening.” In an example, the QCM opening 164 has a diameter DO, which in an example ranges from 3 mm to 8 mm.

In an example, the central cavity 150 has a tiered configuration wherein the top section 152 is wider than the middle section 156, which is wider than the bottom section 154. This tiered configuration defines a ledge 153 in the top section 152, a ledge 155 in the bottom section 154 and a ledge 157 in the middle section 156.

As best seen in FIG. 4, the top surface 142 of lid 140 includes a groove 244 that runs around the flange opening 162 and that supports an O-ring 246.

QCM Assembly

The QCM assembly 300 as disclosed herein is operably arranged in the lid 140. Thus, in an example, the lid 140 constitutes a component of QCM assembly 300. FIG. 5A is a close-up cross-sectional exploded view of the central portion of lid 140 of FIG. 4 and the QCM assembly 300. FIG. 5B is similar to FIG. 5A but shows the QCM assembly 300 in its assembled form and shows the base 170 of reactor chamber 120 and the wafer 200 residing in the interior 176 of reactor chamber 120.

The QCM assembly 300 includes a QCM crystal 310 having a front surface 312 and a back surface 314. In an example, the QCM crystal 310 is a 6 MHz quartz crystal actuated by an electrical signal in the 5 MHz to 6 MHz range. The QCM assembly 300 also has a retainer 320. The retainer 320 has an upper surface 322, a lower surface 324, and conductive resilient members 325 that downwardly depend from the lower surface 324. The retainer 320 is disposed immediately adjacent (above) QCM crystal 310 such that the conductive resilient members 325 establish electrical contact with the back surface 314 of QCM crystal 310 while also pressing down on the QCM crystal 310, as described below.

The retainer 320 is electrically connected to a transducer 326 via an electrical cable 344. A suitable transducer 326 is the model STM-2 from Inficon. Thus, the transducer 326 is electrically connected to the QCM crystal 310 via the retainer 320.

The QCM assembly 300 further includes a flange 330 that includes a central portion 350 and an outer portion 360. The central portion 350 that has a lower surface 354. The central portion 350 closely fits within the flange opening 162 and within the top section 152 of central cavity 150, with the lower surface 354 residing just above the ledge 153. The outer portion 360 is annular and has a lower surface 362, which resides upon the top surface 142 of lid 140 and forms a seal with the O-ring 246 when the central portion 350 of the flange 330 resides in the top section 152. The outer portion 360 includes through-holes 370 for mounting the flange 330 to the lid 140 using, for example, securing members 372 such as hex screws (see FIG. 3.).

The central portion 350 of flange 330 operably supports a connector 340. The connector 340 includes an electrical contact member 342 used to establish electrical contact with the upper surface 322 of retainer 320. In an example, the electrical contact member 342 urges the retainer 320 against the ledge 157 to keep the retainer 320 in place within the middle section 156. In another example, a portion of lower surface 354 of central portion 350 is used to keep the retainer 320 in place within the middle section 156 as the retainer 320 pushes down against the QCM crystal 310.

In an example, the connector 340 is a BNC connector or like connector that allows for the electrical cable 344 (e.g., coaxial cable) leading to the transducer 326 to be quickly connected and disconnected. In an example, the transducer 326 is electrically connected to the controller 50 with a second cable 346, which can be a USB cable.

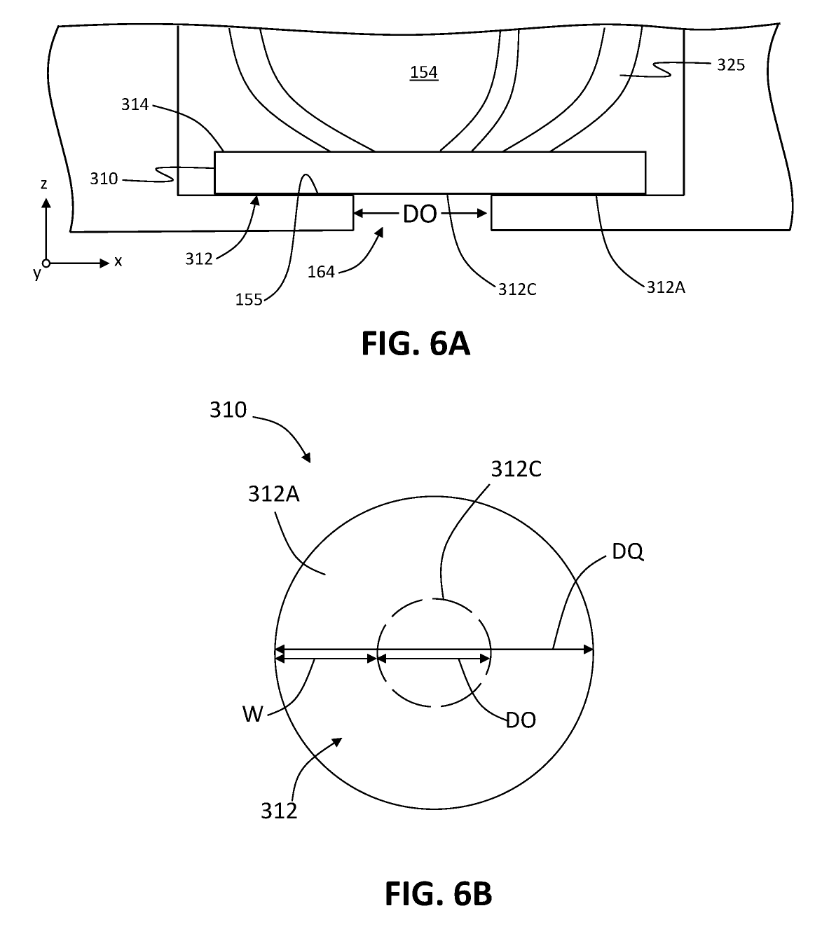

FIG. 6A is a close-up view of QCM crystal 310 operably disposed within the bottom section 154 of central cavity 150 of lid 140, while FIG. 6B is a close-up front on view of the QCM crystal 310. With reference to FIG. 5B, FIG. 6A and FIG. 6B, an annular outer portion 312A of the front surface 312 of QCM crystal 310 rests upon the ledge 155. This configuration leaves a central portion 312C of the front surface 312 residing over the QCM opening 164 of bottom section 154 so that this central portion 312C is exposed to the interior 176 of reactor chamber 120.

During ALD processing, the QCM crystal 310 is driven by the transducer 326 so that the QCM crystal 310 resonates at a select frequency, which is monitored as an output signal from the QCM crystal 310. The reactant products within the interior 176 of reactor chamber 120 deposit on the QCM crystal 310 in the central portion 312C. This deposition changes the resonant frequency of the QCM crystal 310, thereby providing a measurement of amount of material deposited, while the rate of change of the resonant frequency corresponds to the deposition rate.

In an example, the QCM crystal 310 has a diameter DO of 14 mm diameter while the QCM opening 164 in the bottom section 154 has a diameter DO of about 3 mm to 8 mm, with an exemplary diameter DO=4.25 mm. In an example, DO is in the range (0.2)DQ≦DO≦(0.6)DQ, while in another example is in the range (0.25)DQ≦DO≦(0.4)DQ.

The annular outer portion 312A of the front surface 312 that is in contact with the ledge 155 has an area AA while the exposed central portion 312C has an exposed area AE. In an example the annular width W=(DQ−DO)/2 of the annular outer portion 312A is about 5 mm. The area AA of the annular outer portion 312A is given by AA=πW². For a diameter DQ of 14 mm and a diameter DO of 4 mm, W=5 mm and the area AA=π(5 mm)²=78.5 mm². Meanwhile, the exposed area AE=π(2 mm)²=12.56 mm². This gives a ratio R=AA/AE=6.25. In an example, the ratio R is between 2 and 11 or more preferably between 4 and 8.

The relatively large area AA of annular outer portion 312A relative to the exposed area AE of central portion 312C serves several important functions. First, it enables the electrical grounding of QCM crystal 310 to the lid 140. Second, it substantially prevents or limits the transport of gas reactants within the interior 176 of reactor chamber 120 to the back surface 314 of QCM crystal 310. This in turn substantially prevents or limits parasitic reactions that can impede the proper operation of QCM crystal 310. Third, it provides mechanical support and mechanical stability to the QCM crystal 310, thereby limiting the amount of stress on the QCM crystal 310 during sudden pressure changes that can occur within the interior 176 of reactor chamber 120 during ALD processing, e.g., during vent and pump-down sequences. Fourth, it provides good thermal contact between the QCM crystal 310 and the large thermal mass of lid 140 so that the temperature of QCM crystal 310 can equilibrate rapidly.

The retainer 320 resides in the middle section 156 of central cavity 150 and in an example rests upon the ledge 157. The conductive resilient members 325 are in electrical contact with the back surface 314 of QCM crystal 310 and provide a downward force that presses the annular outer portion 312A of front surface 312 of the QCM crystal 310 against the ledge 155. This serves to seal the QCM crystal 310 to the ledge 155 within the bottom section 154 without the need for a sealing material such as an adhesive or an epoxy, or a sealing member such as an O-ring, or the flow of a purge gas in the central cavity 150 (particularly in the bottom section 154) to prevent unwanted film deposition during the ALD process.

As noted above, the central portion 350 of flange 330 is inserted into the top section 152 of central cavity 150 through the flange opening 162 and resides closely therein, while the lower surface 362 of the outer portion 360 of the flange 330 resides upon the top surface 142 of lid 140. In an example, the flange 330 is fixed to the lid 140 using the securing members 372 that pass through the through-holes 370 and into the underlying lid 140. In an example, the through-holes 370 are threaded and aligned with threaded holes (not shown) in the lid 140. The O-ring 246 forms a seal between the flange 330 and the lid 140 that isolates the central cavity 150 from the outside environment.

When the flange 330 is operably arranged with the lid 140, the electrical contact member 342 of connector 340 provides electrical contact with the upper surface 322 of retainer 320, thereby establishing an electrical path (electrical contact) between the QCM crystal 310, the transducer 326 and the controller 50.

The geometry of central cavity 150 and in particular ledge 155 is such that the exposed central portion 312C of front surface 312 of QCM crystal 310 is substantially parallel to the upper surface 202 of semiconductor substrate (wafer) 200. In addition, the exposed central portion 312C is located in close proximity to the upper surface 202 of semiconductor substrate (wafer) 200, e.g., about 7 mm away for interior height h=5 mm. This ensures that both the exposed central portion 312C of the QCM crystal 310 and the upper surface 202 of semiconductor substrate (wafer) 200 that resides within the interior 176 of reactor chamber 120 are exposed to substantially the same amount of ALD reactants. The deposition rates on the exposed central portion 312C and on the upper surface 202 of semiconductor substrate (wafer) 200 may be different since the two surfaces are usually made of different materials (e.g., quartz and silicon, respectively). However, the deposition rates can be related to each other based on theory or empircal data, with the assumption that their respective exposure to the ALD reactants is substantially the same.

As noted above, the configuration of QCM assembly 300 ensures that the QCM crystal 310 is closely thermally coupled to the lid 140 of reactor chamber 120 so that the temperature of the QCM crystal 310 equilibrates rapidly with the temperature of the lid 140 and the reactor chamber 120. This is achieved in part by the annular outer portion 312A of QCM crystal 310 having the relatively large annular contact area AA for efficient thermal transfer. The form factor and thermal mass of flange 330 also provides for rapid thermal equilibration.

The volume and form factor of central cavity 150 has been substantially minimized to limit the amount of space adjacent the back surface 314 of the QCM crystal 310. For example, the central portion 350 of flange 330 downwardly extends into the top section 152 of central cavity 150 and resides in close proximity to the upper surface 322 of retainer 320. This limits the amount of gas that can reside adjacent the back surface 314 while enabling rapid equilibration of the QCM reading after setting the interior 176 of reactor chamber 120 under vacuum.

In an example, the QCM assembly 300 is configured to be operated under vacuum down to 1 mTorr and heated to temperatures up to 350° C.

It will be apparent to those skilled in the art that various modifications to the preferred embodiments of the disclosure as described herein can be made without departing from the spirit or scope of the disclosure as defined in the appended claims. Thus, the disclosure covers the modifications and variations provided they come within the scope of the appended claims and the equivalents thereto.

What is claimed is:

1. A quartz crystal microbalance (QCM) assembly for an atomic-layer deposition (ALD) system having a reactor chamber with an interior, comprising:
a lid of the reactor chamber, the lid having a central cavity;
a QCM crystal having a front surface, a back surface and a diameter DQ and disposed in a bottom section of the central cavity with the front surface in contact with a ledge so that a central portion of the front surface resides adjacent a QCM opening having a diameter DO, so that the central portion of the front surface is exposed to the interior through the QCM opening, and wherein (0.25)DQ≦DO≦(0.6)DQ;
a retainer having an upper surface and downwardly depending conductive resilient members, the retainer arranged within the central cavity with the conductive resilient members in electrical contact with the QCM crystal while pressing an outer portion of the front surface of the QCM crystal against the ledge to form a first seal between the front surface of the QCM crystal and the ledge; and
a flange having a central portion that closely resides within a top section of the central cavity and immediately adjacent the retainer, the flange having an outer portion with a lower surface that resides immediately adjacent a top surface of the lid and that forms a second seal therewith, the flange operably supporting an electrical contact member that makes electrical contact with the retainer.

2. The QCM assembly according to claim 1, wherein the first seal does not include either a sealing material or a sealing member.

3. The QCM assembly according to claim 1, wherein there is no flow of a purge gas within the central cavity.

4. The QCM assembly according to claim 1, wherein (0.25)DQ≦DO≦(0.4)DQ.

5. The QCM assembly according to claim 1, further comprising a transducer electrically connected to the retainer through the flange.

6. The QCM assembly according to claim 5, further comprising a controller electrically connected to the transducer.

7. The QCM assembly according to claim 1, further comprising a base operably attached to the lid to define the reactor chamber.

8. The QCM assembly according to claim 7, further comprising a thermally insulating cover sized to cover the reactor chamber.

9. The QCM assembly according to claim 1, wherein the interior of reactor chamber has a height in the range from 3 mm to 50 mm.

10. A quartz crystal microbalance (QCM) assembly for an atomic-layer deposition (ALD) system having a reactor chamber with a lid, comprising:
the lid, wherein the lid has a top surface, a bottom surface and a central cavity that includes a flange opening at the top surface that leads to a top section of the central cavity and a QCM opening at the bottom surface that leads to a bottom section of the central cavity, wherein the QCM opening has a diameter DO defined by a ledge, wherein the central cavity has a middle section between the top and bottom sections, and wherein the top surface includes an O-ring groove that runs around the central cavity and that operably supports an O-ring;
a QCM crystal having a front surface, a back surface and a diameter DQ and disposed in the bottom section of the central cavity with the front surface in contact with the ledge so that a central portion of the front surface resides adjacent the QCM opening, and wherein (0.25)DQ≦DO≦(0.6)DQ;
a retainer arranged in the middle section of the central cavity, the retainer having an upper surface and downwardly depending conductive resilient members that contact the back surface of the QCM crystal and press an outer portion of the front surface of the QCM crystal into the ledge to form a first seal; and
a flange having a central portion that closely resides within the top section of the central cavity and having an outer portion with a lower surface that resides immediately adjacent the top surface of the lid and that forms a second seal with the O-ring, the flange operably supporting a connector that includes an electrical contact member that makes electrical contact with the retainer.

11. The QCM assembly according to claim 10, wherein (0.25)DQ≦DO≦(0.4)DQ.

12. The QCM assembly according to claim 10, further comprising a transducer electrically connected to the retainer.

13. The QCM assembly according to claim 12, further comprising a controller electrically connected to the transducer.

14. The QCM assembly according to claim 10, further comprising a base operably attached to the lid to define the reactor chamber.

15. The QCM assembly according to claim 14, further comprising a thermally insulating cover sized to cover the reactor chamber.

16. A method of performing an in situ measurement of film growth in an atomic-layer deposition (ALD) system that includes a reactor chamber having an interior defined by a base and a lid and that operably supports a substrate, comprising:
providing a quartz crystal microbalance (QCM) assembly integrated with the lid, the QCM assembly having a QCM crystal with a front surface and disposed on a ledge in a bottom section of a cavity formed in the lid so that a central portion of the QCM crystal is exposed to the interior of reactor chamber and above the substrate while a retainer presses an outer portion of the front surface of the QCM crystal against the ledge to form a seal that does not include either a sealing material or a sealing member; and
performing an ALD process in the interior of reactor chamber to deposit a first film on the substrate and a second film on the central portion of the QCM crystal while driving the QCM crystal with a transducer and measuring an output signal from the QCM crystal.

17. The method according to claim 16, wherein the QCM crystal has a diameter DQ, the central portion of the surface of QCM crystal has a diameter DO, and wherein (0.25)DQ≦DO≦(0.6)DQ.

18. The method according to claim 17, wherein said pressing is performed by downwardly depending conductive resilient members of the retainer that resides immediately above the QCM crystal and within the cavity in the lid.

19. The method according to claim 17, further comprising thermally insulating the QCM assembly with a thermally insulated cover disposed over the lid.

20. The method according to claim 17, wherein the interior has a height in the range from 3 mm to 50 mm.

21. A quartz crystal microbalance (QCM) assembly for an ALD system, comprising:
a lid of a reactor chamber of the ALD system, the lid having a central cavity with a bottom section that includes a ledge that defines an opening to an interior of the reactor chamber;
a QCM crystal with a front surface, the QCM crystal being disposed in the bottom section of the central cavity with an outer portion of the front surface in contact with the ledge so that a central portion of the front surface is exposed to the reactor chamber through the opening;
a retainer arranged within the central cavity above the QCM crystal, the retainer configured to press the outer portion of the QCM crystal against the ledge to form a seal between the front surface of the QCM crystal and the ledge while also forming electrical contact between the retainer and the QCM crystal;
a flange disposed immediately adjacent a top surface of the lid and that seals the central cavity while providing electrical contact with the QCM crystal through the retainer; and
a transducer external to the reactor chamber and that is electrically connected to the QCM crystal through the flange and the retainer.
